(19) United States
(12) Patent Application Publication
(10) Pub. No.: US 2012/0126320 A1
(43) Pub. Date: May 24, 2012

(54) METHOD FOR MANUFACTURING A MOS-FIELD EFFECT TRANSISTOR

(75) Inventors: Rohan S. Braithwaite, Gilbert, AZ (US); Gregory Dix, Tempe, AZ (US)

(73) Assignee: Microchip Technology Incorporated

(21) Appl. No.: 13/291,289

(22) Filed: Nov. 8, 2011

Related U.S. Application Data
(60) Provisional application No. 61/415,110, filed on Nov. 18, 2010.

(51) Int. Cl. H01L 27/092; H01L 21/336

(52) U.S. Cl. 257/337; 438/286; 257/E21.417; 257/E27.062

(57) ABSTRACT

A method for manufacturing a Power Metal-Oxide-Semiconductor Field-Effect-Transistor (MOSFET) has the steps of: implanting a base region of the Power MOSFET within an epitaxial layer of a semiconductor chip comprising an insulated gate structure, implanting a source link region on one side of the gate through a first mask, wherein the first mask is partially formed by an edge of the gate, the source link extending from a surface into the epitaxial layer and having a width defined by the first window, subsequently forming a spacer extending from the edge of the gate which defines the first window and forming a second mask which is partially formed by the spacer, and implanting a source region through the second mask.

### CROSS-REFERENCE TO RELATED APPLICATIONS

This application claims the benefit of U.S. Provisional Application No. 61/415,110 filed on Nov. 19, 2010, entitled “LOW SOURCE RESISTANCE CHANNEL LINK FOR DMOS INTEGRATED IN A SPACER TECHNOLOGY”, which is incorporated herein in its entirety.

### TECHNICAL FIELD

This application concerns a method for manufacturing a MOS-Field Effect Transistor (FET).

### BACKGROUND

Power metal oxide semiconductor field-effect transistors (MOSFET) are generally used to handle high power levels in comparison to small signal transistors in integrated circuits and therefore comprise different characteristics and different steps in a manufacturing process. Such power transistors can be formed laterally or vertically within a semiconductor chip. In particular lateral Power MOSFETs can be integrated into existing modules thus enhancing such devices. As shown in FIG. 4, to manufacture such a device, an N⁻ epitaxial layer 330 is formed on a generally heavily doped N⁺ substrate 310. A buried layer 320 is implanted to be able to separate the transistor from other devices formed within the epitaxial layer. To this end, field oxides 340 may be used to define a specific area within the epitaxial layer 330. This field oxide may also be extended and used to insulate a polysilicon gate 380. The gate 380 is then used as a mask to implant the P-base regions 350 and source 360, wherein an N⁺ doped source region 360 extends from the top into the epitaxial layer 330 on one side of the gate 380 surrounded by a P-doped region 350 which forms the P-base. The P-base is created to extend under the gate such that the area of the P-base regions 350 covered by the gate 380 can form a channel of the MOSFET. A drain region 370 is formed on the other side of the gate 380.

To improve the breakdown voltage between source and drain, such a transistor is usually formed with a lightly doped drain (LDD) which requires a low concentration impurity layer between the source and drain. LDD MOSFETs provide an advantage because the low concentration impurity layer moderates an electrical field in the vicinity of the gate. Thus, a reduction of the breakdown voltage between source and drain, a reduction of the threshold voltage and the generation of hot carriers can be prevented. Normally such a transistor is formed in a self aligned manner using ion implantation of an impurity 395 into the epitaxial layer by using the gate 380 as a mask.

When integrating a Power transistor within an existing technology, for example, into a module, such an integration brings many challenges with it. For example, the existing technology may be a spacer process technology. For cost reasons it makes sense to reuse as much of the existing modules as possible. That means typically that the Gate electrode formed by the standard spacer process technology would be the same for the Power transistor, and the heavy source drain implants would also be the same. Because of the spacer and the existing thermal budget, the heavy source drain would not reach the side of the gate electrode, causing an electrical disconnect between the transistor channel and the source of the device.

In such a spacer process technology, spacers 390 are formed on the side of the gate 380. The spacers are used after the low impurity layer 395 is formed to form a self-aligned highly doped source 360 using the spacer 390 as a mask.

If the Power transistor is to be integrated into an integrated module having a variety of integrated circuit structures as mentioned above, the above mentioned heavy drive for implanting the P-base regions may not be available because it has an impact on the overall thermal budget in a manufacturing process. These budgets are often at their limit and do not allow for additional thermal energy without having an impact on the functionality of the integrated components. Thus, changing an existing thermal budget is often not an available option. A lower doping of the source 360 may however lead to a cut off of the source from the channel. Therefore a need exists for a manufacturing process that allows to combine power transistors using a spacer technology with existing integrated structures in a manufacturing process without changing the thermal budget or without exceeding the thermal budget.

### SUMMARY

According to an embodiment, a method for manufacturing a Power Metal-Oxide-Semiconductor Field-Effect-Transistor (MOSFET) may comprise: implanting a base region of said Power MOSFET within an epitaxial layer of a semiconductor chip comprising an insulated gate structure, implanting a source link region on one side of the gate through a first mask, wherein the first mask is partially formed by an edge of the gate, said source link extending from a surface into the epitaxial layer and having a width defined by said first window, subsequently forming a spacer extending from the edge of said gate which defines said first window and forming a second mask which is partially formed by said spacer, and implanting a source region through said second mask.

According to a further embodiment, the first and second mask can be dimensioned such that the source link extends from about the edge of the gate to the edge of the source region. According to a further embodiment, the first and second mask can be dimensioned such that the source link extends from about the edge of the gate into the source region. According to a further embodiment, the variables of the implanting of the source link can be dimensioned to define a breakdown voltage of said Power MOSFET. According to a further embodiment, the variables of the implanting of the source link can be dimensioned to define an on-resistance of said Power MOSFET. According to a further embodiment, the MOSFET can be formed within a single manufacturing process for forming a plurality of integrated devices and said MOSFET in the semiconductor chip. According to a further embodiment, the plurality of devices may form a microcontroller controlling said MOSFET. According to a further embodiment, the plurality of devices may form a pulse width modulator controlling said MOSFET. According to a further embodiment, at least two MOSFETs can be formed during said manufacturing process and a drain of a first MOSFET is connected to a source of a second MOSFET. According to a further embodiment, a plurality of MOSFETs can be formed during said manufacturing process and said plurality of MOSFETs are interconnected to form an H-bridge. According to a further embodiment, the base MOSFET can be formed within an area defined by surrounding field oxide. According to a further embodiment, the method may further comprise the step of forming a buried layer prior to the implanting step. According to a further embodiment, the method may further comprise the step of forming a drain region on the other side of the gate extending from a top surface into the epitaxial layer. According to a further embodiment, the method may further comprise the step of forming a plurality of transistor cells within said epitaxial layer and forming metal layers to interconnect said gates, drain and source regions of said plurality of transistor cells.

According to another embodiment, a Power Metal-Oxide-Semiconductor Field-Effect-Transistor (MOSFET) may comprise: a base region of said Power MOSFET implanted within an epitaxial layer of a semiconductor chip comprising an insulated gate structure, a source link region implanted on one side of the gate through a first mask, wherein the first mask is partially formed by an edge of the gate, said source link extending from a surface into the epitaxial layer and having a width defined by said first window, a spacer extending from the edge of said gate which defines said first window and forming a second mask which is partially formed by said spacer, and a source region implanted through said second mask.

According to a further embodiment, the first and second mask can be dimensioned such that the source link extends from about the edge of the gate to the edge of the source region. According to a further embodiment, the first and second mask can be dimensioned such that the source link extends from about the edge of the gate into the source region. According to a further embodiment, the variables of the implanting of the source link can be dimensioned to define a breakdown voltage of said Power MOSFET. According to a further embodiment, the variables of the implanting of the source link can be dimensioned to define an on-resistance of said Power MOSFET. According to a further embodiment, the MOSFET can be formed within a single manufacturing process for forming a plurality of integrated devices and said MOSFET in the semiconductor chip. According to a further embodiment, the plurality of devices may form a microcontroller controlling said MOSFET. According to a further embodiment, the plurality of devices may form a pulse width modulator controlling said MOSFET. According to a further embodiment, at least two MOSFETs can be formed during said manufacturing process and a drain of a first MOSFET is connected to a source of a second MOSFET. According to a further embodiment, a plurality of MOSFETs can be formed during said manufacturing process and said plurality of MOSFETs are interconnected to form an H-bridge. According to a further embodiment, the base MOSFET can be formed within an area defined by surrounding field oxide. According to a further embodiment, the Power Metal-Oxide-Semiconductor Field-Effect-Transistor may further comprise a buried layer. According to a further embodiment, the Power Metal-Oxide-Semiconductor Field-Effect-Transistor may further comprise a drain region on the other side of the gate extending from a top surface into the epitaxial layer. According to a further embodiment, the Power Metal-Oxide-Semiconductor Field-Effect-Transistor may further comprise a plurality of transistor cells within said epitaxial layer and metal layers to interconnect said gates, drain and source regions of said plurality of transistor cells.

### BRIEF DESCRIPTION OF THE DRAWINGS

FIG. 1 shows an embodiment a power MOS-FET manufactured according to an embodiment;

FIG. 2A-2D shows certain manufacturing steps for the embodiment shown in FIG. 1;

FIG. 3A, 3B shows a block diagram of a semiconductor module, such as a microcontroller, integrated with power MOSFETs according to various embodiments; and

FIG. 4 shows a conventional power transistor manufactured using a spacer technology.

### DETAILED DESCRIPTION

According to various embodiments, a DMOS source implant which is implemented before the spacer is put down can be used to overcome the above mentioned issues. Also, it is known that the doping level of the DMOS source implant can adversely affect the performance of the device. If the doping is too high (basically at the level of the existing heavy source/drain implant), it will cause a shortening of the channel and a reduction in the operating voltage of the transistor. If the doping is too low (basically at a level of the existing LDD in the original process), it would affect the on Resistance of the transistor. This implant must therefore be optimized. According to further embodiments, the existing heavy doping is used only around the contact regions of the device. The DMOS implant basically forms the Source implant for the device.

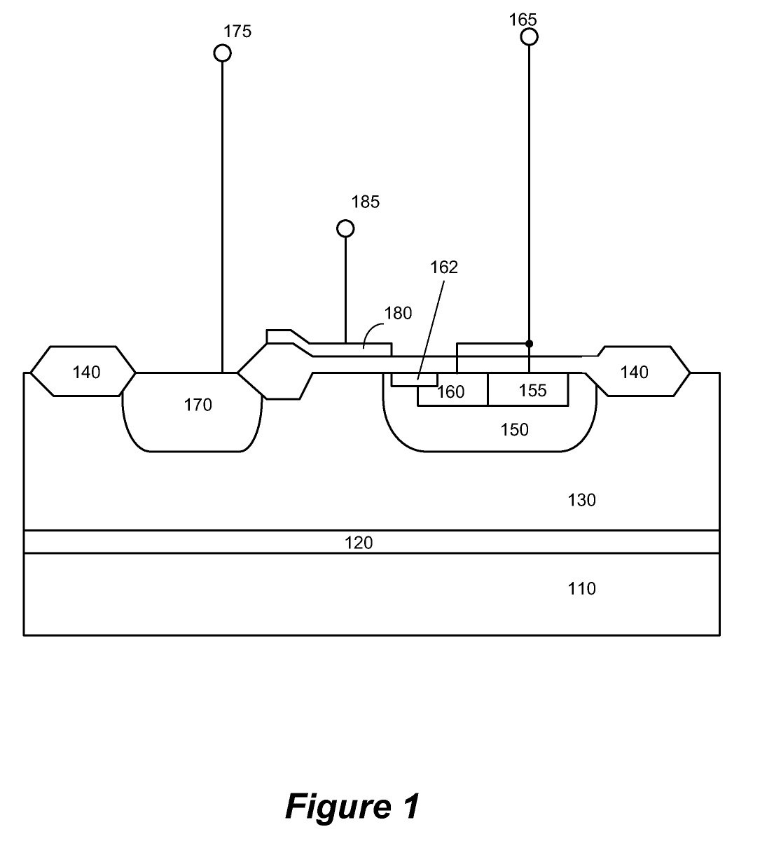

FIG. 1 shows a cross-sectional view of a lateral Power-MOS-FET which can be manufactured according to various embodiments. A N+ doped substrate 110 is provided on top of which an N−epitaxial layer 130 is formed which for creating high voltage power transistors. Between the epitaxial layer 130 and the substrate 110 there can be an N doped buried layer (NBL) 120 used for forming a well or insulating the transistor from other devices formed within the epitaxial layer 130. Also, for separation of the transistor from other structures there is a field oxide 140 formed on the top of the epitaxial layer 130 which may extend into the epitaxial layer 130. The field oxide 140 may also be used and structured to form an insulated gate 180 above the epitaxial layer 130. Within the area defined by the field oxide 140, from the top into the epitaxial layer 130 on the right side of the gate 180 as shown in FIG. 1, there extends a P-doped base region 150 within which a source region 160 is formed. The P-base 150 is connected with the source region 160 through a contact zone 155 and an interconnecting metal layer 165. A drain region 170 is formed on the left side of the gate 180 adjoining the field oxide 140. An area between the drain and source regions 170, 160 within the P-base region 150 which is covered by the gate 180 can form a channel if an appropriate voltage is applied to the gate 180. The source region 160 is formed using a spacer technology as will be explained in more detail below. To provide a sufficient link between the source 160 and the channel region, an additional N-doped source link 162 is provided which extends from within the source region 160 to the edge of the gate 180 or from the edge of the source region 160 to the edge of the channel as defined by the edge of gate 180. Gate 180 and drain 170 are connected with respective metal layers 185 and 175, respectively. With appropriate voltage applied to the source, drain and gate, the channel can be formed within the P-base 150 between the source link 162 and the epitaxial layer 130 through P-base region allowing for current to flow from the source to the drain. The source link 162 provides a secure link to the source region 160 which is spaced apart from the gate 180 to enhance the breakdown voltage and avoid hot carrier injection without having an impact on the thermal budget in an existing process.

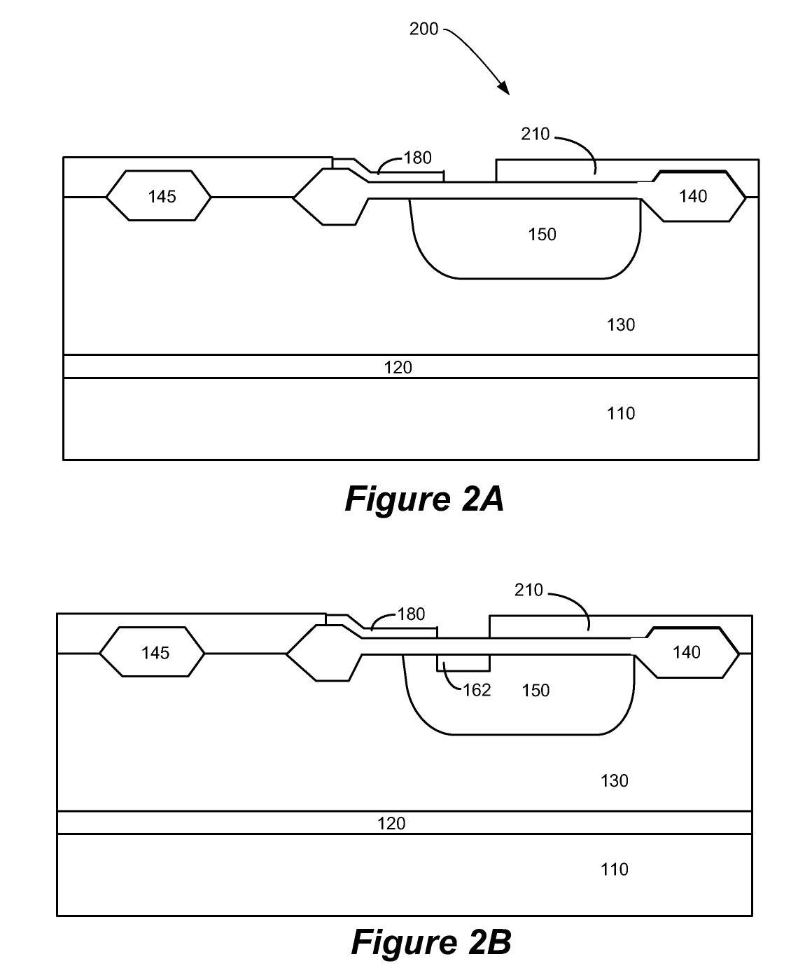

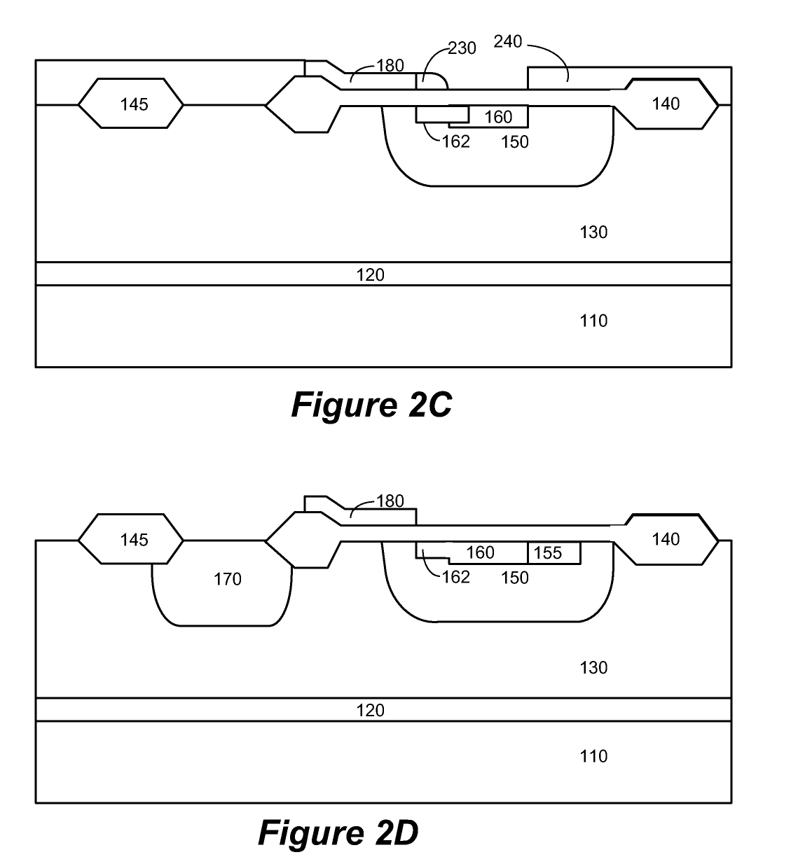

FIG. 2A-2D show exemplary process steps for manufacturing a device as shown in FIG. 1. As shown in FIG. 2A, on an N−doped epitaxial layer 110 an N+ substrate 130 has been grown and a buried layer 120 has been formed between the substrate and the epitaxial layer 130. On top of the epitaxial layer 110 an oxide layer 140 is either formed or deposited and patterned for depositing a gate 180. As shown in FIG. 2A, filed oxide 140 can be structured to allow formation of a stepped gate 180 using for example polysilicon. A base region 150 can be formed by ion implantation for example as disclosed in co-pending U.S. patent application Ser. No. ______ “Method for manufacturing a MOS-Field Effect Transistor”, by Rohan S. Braithwaite, Gregory Dix, and Harold Kline based on U.S. Provisional Application No. 61/415,464 filed on Nov. 19, 2010, entitled “USING AN ANGLED IMPLANT TO FORM A P-BASE REGION” which is hereby incorporated by reference. A photo-mask 210 may then be applied to define a window 215 which extends from the right side of gate 180 into the P-base region 150.

Using ion-implantation, as shown in FIG. 2B, a relatively short source link 162 extends from the edge of the channel as defined by the edge of gate 180 which is used as a mask into the P-base region 150. The width of this source link 162 may be defined according to the later placement of the source region. It can substantially overlap but not exceed the later implanted source region 150.

FIG. 2C shows the application of a spacer 230 and a formation of source photo mask 240 and associated window through which again by means of ion implantation, a source region 160 is implanted. The Spacer material can be a combination of various oxide types or nitride. It can be created with a photo process. As shown in FIG. 2C, the spacer 230 may be dimensioned such that source link 162 overlaps with the source region 160. However, as stated above, a substantial overlap is not necessary as long as a good coupling is established between the source 160 and source link 162. Thus, the spacer 230 could have the same width as source link 162.

FIG. 2D shows the final transistor after implanting of the drain region 170 and the base contact region 155 and removal of any photo mask and/or spacer. As can be seen, the source link 162 can be seen as merged with source region 160. Even though FIG. 2D shows a specific relationship with respect to width and depth of source link 162, the source link 162 can be dimensioned differently according to the process and desired transistor specification. Thus, the source link 162 can be as deep as source region 160 or reach even deeper. Metal layers can then be used to connect the source/P-base, gate and drain with respective contacts.

In particular, the source link 162 can be formed by ion-implantation, for example an E14 cm-2 type implant. According to various embodiments, the exact dose and energy would have to be optimized for the specific device specification for Rdson and breakdown. For example, a 5E14 cm-2 Arsenic implant at 80 KeV can be used. Depending on the manufacturing technology, of course other values may apply.

Furthermore, the source link 162 can be dimensioned to optimize the device break down voltage and/or the replacement of the baseline N+ source drain implants which would be necessary. For example, such implants could now be replaced by lighter implants to form the source/drain regions of the power device. Thus, no changes to the baseline flow with respect to the thermal impact are needed.

Adding an implant after the spacer 230 would require the use of a higher dose and, thus additional thermal cycle to get the dopants underneath the spacer which again would change the baseline device. Thus, source link implantation before the formation of the spacer according to various embodiments ensures that the entire process complies with the thermal requirements for the entire device.

The embodiments in FIGS. 1-2 show a single cell of respective MOSFETs. The drain and source regions may have a stripe structure. According to other embodiments the cells can however have a square form, a hexagonal shape or any other suitable cell shape for which the principle of the various embodiments can be applied to. The cell structure or a plurality of cells can be used to form a power DMOS-FET within an integrated circuit or in a discrete transistor device. As mentioned above, a module having multiple power transistors may be combined with a driver, a modulation device or a microcontroller. Such modules can be integrated within the existing process flow of such devices without changing the thermal budget. Thus, no additional thermal steps are needed and no changes in the baseline devices will occur. Such an integrated circuit may provide control circuits for example for use in a switched mode power supply that integrates a modulator and/or microcontroller with the power transistors. Thus, no external power transistors may be necessary in respective applications.

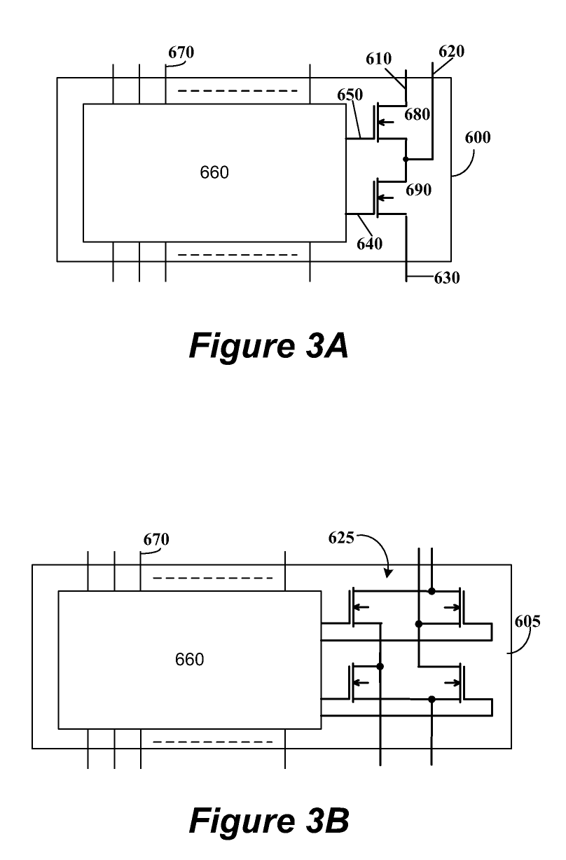

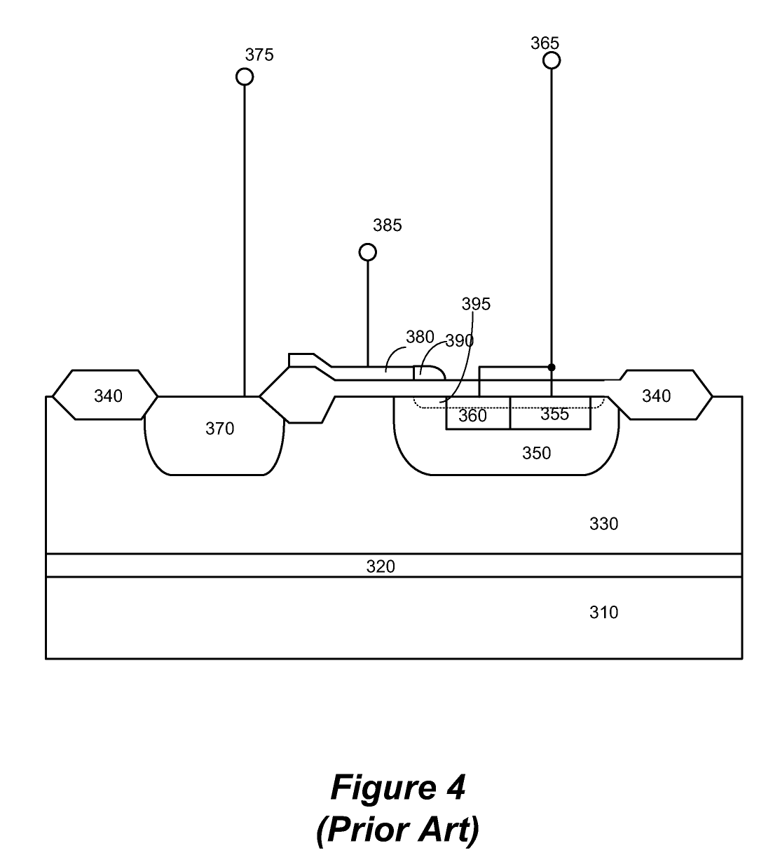

FIG. 3A shows schematically how a microcontroller 660 can be combined with two power transistors 680 and 690 on a single chip 600. Microcontroller 660 may have a plurality of peripheral devices such as controllable drivers, modulators, in particular pulse width modulators, timers etc. and is capable to drive the gates 640 and 650 of transistors 680 and 690 directly or through respective additional drivers. The chip 600 can be configured to make a plurality of functions of the microcontroller available through external connections or pins 670. The source of first transistor 680 can be connected to external connection or pin 610. Similarly, external connection 620 provides a connection to the combined drain and source of transistors 680 and 690 and external connection or pin 630 for the drain of the second transistor 630. Other transistor structures manufactured in accordance with the various embodiments disclosed can be used, such as an H-bridge or multiple single transistors. FIG. 3B shows an exemplary plurality of MOSFETs connected to form an H-Bridge 625 that can be coupled with a microcontroller 660 or modulator within a single semiconductor chip 605.

Furthermore, the exemplary embodiment shows a P-channel device with appropriate dopings of the different regions. A person skilled in the art will appreciate that the embodiments of the present application are not restricted to P-channel devices but can be also applied to N-Channel devices.

What is claimed is:

1. A method for manufacturing a Power Metal-Oxide-Semiconductor Field-Effect-Transistor (MOSFET) comprising:
implanting a base region of said Power MOSFET within an epitaxial layer of a semiconductor chip comprising an insulated gate structure,
implanting a source link region on one side of the gate through a first mask, wherein the first mask is partially formed by an edge of the gate, said source link extending from a surface into the epitaxial layer and having a width defined by said first window,
subsequently forming a spacer extending from the edge of said gate which defines said first window and forming a second mask which is partially formed by said spacer, and
implanting a source region through said second mask.

2. The method according to claim 1, wherein the first and second mask are dimensioned such that the source link extends from about the edge of the gate to the edge of the source region.

3. The method according to claim 1, wherein the first and second mask are dimensioned such that the source link extends from about the edge of the gate into the source region.

4. The method according to claim 1, wherein the variables of the implanting of the source link are dimensioned to define a breakdown voltage of said Power MOSFET.

5. The method according to claim 1, wherein the variables of the implanting of the source link are dimensioned to define an on-resistance of said Power MOSFET.

6. The method according to claim 1, wherein the MOSFET is formed within a single manufacturing process for forming a plurality of integrated devices and said MOSFET in the semiconductor chip.

7. The method according to claim 6, wherein the plurality of devices form a microcontroller controlling said MOSFET.

8. The method according to claim 6, wherein the plurality of devices form a pulse width modulator controlling said MOSFET.

9. The method according to claim 6, wherein at least two MOSFETs are formed during said manufacturing process and a drain of a first MOSFET is connected to a source of a second MOSFET.

10. The method according to claim 6, wherein a plurality of MOSFETs are formed during said manufacturing process and said plurality of MOSFETs are interconnected to form an H-bridge.

11. The method according to claim 1, wherein the base MOSFET is formed within an area defined by surrounding field oxide.

12. The method according to claim 11, further comprising the step of forming a buried layer prior to the implanting step.

13. The method according to claim 1, further comprising forming a drain region on the other side of the gate extending from a top surface into the epitaxial layer.

14. The method according to claim 13, further comprising forming a plurality of transistor cells within said epitaxial layer and forming metal layers to interconnect said gates, drain and source regions of said plurality of transistor cells.

15. A Power Metal-Oxide-Semiconductor Field-Effect-Transistor (MOSFET) comprising:
a base region of said Power MOSFET implanted within an epitaxial layer of a semiconductor chip comprising an insulated gate structure,
a source link region implanted on one side of the gate through a first mask, wherein the first mask is partially formed by an edge of the gate, said source link extending from a surface into the epitaxial layer and having a width defined by said first window,
a spacer extending from the edge of said gate which defines said first window and forming a second mask which is partially formed by said spacer, and
a source region implanted through said second mask.

16. The Power Metal-Oxide-Semiconductor Field-Effect-Transistor according to claim 15, wherein the first and second mask are dimensioned such that the source link extends from about the edge of the gate to the edge of the source region.

17. The Power Metal-Oxide-Semiconductor Field-Effect-Transistor according to claim 15, wherein the first and second mask are dimensioned such that the source link extends from about the edge of the gate into the source region.

18. The Power Metal-Oxide-Semiconductor Field-Effect-Transistor according to claim 15, wherein the variables of the implanting of the source link are dimensioned to define a breakdown voltage of said Power MOSFET.

19. The Power Metal-Oxide-Semiconductor Field-Effect-Transistor according to claim 15, wherein the variables of the implanting of the source link are dimensioned to define an on-resistance of said Power MOSFET.

20. The Power Metal-Oxide-Semiconductor Field-Effect-Transistor according to claim 15, wherein the MOSFET is formed within a single manufacturing process for forming a plurality of integrated devices and said MOSFET in the semiconductor chip.

21. The Power Metal-Oxide-Semiconductor Field-Effect-Transistor according to claim 20, wherein the plurality of devices form a microcontroller controlling said MOSFET.

22. The Power Metal-Oxide-Semiconductor Field-Effect-Transistor according to claim 20, wherein the plurality of devices form a pulse width modulator controlling said MOSFET.

23. The Power Metal-Oxide-Semiconductor Field-Effect-Transistor according to claim 20, wherein at least two MOSFETs are formed during said manufacturing process and a drain of a first MOSFET is connected to a source of a second MOSFET.

24. The Power Metal-Oxide-Semiconductor Field-Effect-Transistor according to claim 20, wherein a plurality of MOSFETs are formed during said manufacturing process and said plurality of MOSFETs are interconnected to form an H-bridge.

25. The Power Metal-Oxide-Semiconductor Field-Effect-Transistor according to claim 15, wherein the base MOSFET is formed within an area defined by surrounding field oxide.

26. The Power Metal-Oxide-Semiconductor Field-Effect-Transistor according to claim 25, further comprising a buried layer.

27. The Power Metal-Oxide-Semiconductor Field-Effect-Transistor according to claim 15, further comprising a drain region on the other side of the gate extending from a top surface into the epitaxial layer.

28. The Power Metal-Oxide-Semiconductor Field-Effect-Transistor according to claim 27, further comprising a plurality of transistor cells within said epitaxial layer and metal layers to interconnect said gates, drain and source regions of said plurality of transistor cells.
